(19) United States
(12) Patent Application Publication
(10) Pub. No.: US 2026/0324004 A1
(43) Pub. Date: Oct. 15, 2026

(54) OXIDE SEMICONDUCTOR DEVICE AND SEMICONDUCTOR MEMORY DEVICE INCLUDING THE SAME

(71) Applicant: SK hynix Inc., Icheon-si (KR)

(72) Inventor: Jae Gil LEE, Icheon-si (KR)

(21) Appl. No.: 19/423,747

(22) Filed: Dec. 17, 2025

(30) Foreign Application Priority Data
Apr. 10, 2025 (KR) 10-2025-0046737

(51) Int. Cl. H10D 30/67; H10B 12/00; H10D 62/60

(52) U.S. Cl. CPC H10D 30/6756; H10B 12/482; H10B 12/488; H10D 30/673; H10D 30/6738; H10D 30/6757; H10D 62/60

(57) ABSTRACT

An oxide semiconductor device may include an active region, a gate, a source electrode and a drain electrode, and a degenerated pattern. The active region may include an oxide semiconductor material. The gate may be disposed in the active region. The source electrode and the drain electrode may include a metal material. The source electrode may be arranged at one side of the gate, and the drain electrode may be arranged at the other side of the gate. At least one degenerated pattern may be interposed between the active region and the source electrode, or between the active region and the drain electrode, or both, the degenerated pattern including a metal-rich oxide.

### CROSS-REFERENCE TO RELATED APPLICATION

The present application claims priority under 35 U.S.C. § 119(a) to Korean application number 10-2025-0046737, filed on Apr. 10, 2025, in the Korean Intellectual Property Office, which is incorporated herein by reference in its entirety.

### BACKGROUND

### 1. Technical Field

Embodiments of the present disclosure relate to a semiconductor device, and more particularly, to an oxide semiconductor device and a semiconductor memory device including the same.

### 2. Related Art

A semiconductor memory device may include a plurality of word lines, a plurality of bit lines, and a plurality of memory cells connected between the plurality of word lines and the plurality of bit lines. Each of the memory cells may include an access element including a transistor and a storage element.

As an integration density of the semiconductor memory device increases, an area occupied by the access element and the storage element have been exponentially reduced. In particular, a reduction in the area occupied by the access element may degrade the reliability and a carrier mobility characteristic of the semiconductor memory device.

Recently, a semiconductor memory device using an oxide semiconductor material as a channel layer have been proposed to improve the carrier mobility characteristic and support a low-power operation.

### SUMMARY

Embodiments of the present disclosure provide an oxide semiconductor device capable of improving electrical characteristics.

Embodiments of the present disclosure also provide a semiconductor memory device including the oxide semiconductor device.

According to embodiments, there may be provided an oxide semiconductor device. The oxide semiconductor device may include an active region, a gate, a source electrode and a drain electrode, and a degenerated pattern. The active region may include an oxide semiconductor material. The gate may be disposed on the active region. The source electrode and the drain electrode may include a metal. The source electrode may be disposed on the active region corresponding to one side of the gate. The drain electrode may be disposed on the active region corresponding to the other side of the gate. At least one degenerated pattern may be interposed between the active region and the source electrode, or between the active region and the drain electrode, or both, the degenerated pattern including a metal-rich oxide.

According to embodiments, there may be provided a semiconductor memory device. The semiconductor memory device may include an active region, a word line, a source electrode, a drain electrode, a storage electrode, a bit line, and a degenerated pattern. The active region may include an oxide semiconductor layer disposed on a substrate. The word line may be disposed on the active region. The source electrode may be disposed on a first portion of the active region at one side of the word line. The drain electrode may be disposed on a second portion of the active region at the other side of the word line. The storage electrode may be in contact with the source electrode. The bit line may be in contact with the drain electrode. At least one degenerated pattern may be interposed between the active region and the source electrode, or between the active region and the drain electrode, or both, the degenerated pattern including a metal-rich oxide.

In embodiments, the degenerated pattern may include at least one of In and Zn.

In embodiments, a metal atom concentration of the degenerated pattern may range from about 1×10¹⁹ to about 1×10²¹ cm⁻³.

In embodiments, a Fermi level of the degenerated pattern may be positioned in a conduction band of the degenerated pattern.

According to embodiments, the degenerated pattern containing a high concentration of metal atoms may be interposed between the active region and the source electrode, and between the active region and the drain electrode. Accordingly, a contact resistance of an access transistor including the oxide semiconductor may be improved, thereby securing carrier mobility and enhancing electrical characteristics.

### BRIEF DESCRIPTION OF THE DRAWINGS

The above and other aspects and features of various embodiments of the present disclosure will be more easily understood from the following detailed description taken in conjunction with the accompanying drawings, in which:

FIG. 1 is a plan view of a semiconductor device including an oxide semiconductor channel in accordance with embodiments;

FIG. 2 is a cross-sectional view taken along line I–I′ of FIG. 1;

FIG. 3 is an energy band diagram of an oxide semiconductor material and a degenerated semiconductor in accordance with embodiments;

FIG. 4 is an energy band diagram of a junction between a source electrode and a first degenerated pattern in accordance with embodiments;

FIG. 5 is a schematic plan view of a DRAM memory cell in accordance with embodiments; and

FIGS. 6 and 7 are schematic perspective views of a DRAM memory cell in accordance with embodiments.

### DETAILED DESCRIPTION

Beneficial aspects and features of embodiments of the present disclosure, and methods for achieving them, will become apparent with reference to some embodiments described in detail below in conjunction with the accompanying drawings. However, various embodiments of the present disclosure are not limited to the embodiments set forth herein and may be embodied in various different forms. Rather, these embodiments are provided so that this disclosure may be thorough and complete, and convey scopes of various embodiments of the present disclosure to those skilled in the art to which the present disclosure pertains.

In the drawings, sizes and relative dimensions of layers and regions may be exaggerated for clarity of description. Throughout the specification, like reference numerals may refer to like elements. Throughout the specification and claims, a list of items prefaced by a phrase such as “at least one of” or “one or more of” or “one or both of” indicates an inclusive list. For example, a list of “at least one of A and B” and a list of “one or both of A and B” each indicate A, or B, or AB (i.e., A and B).

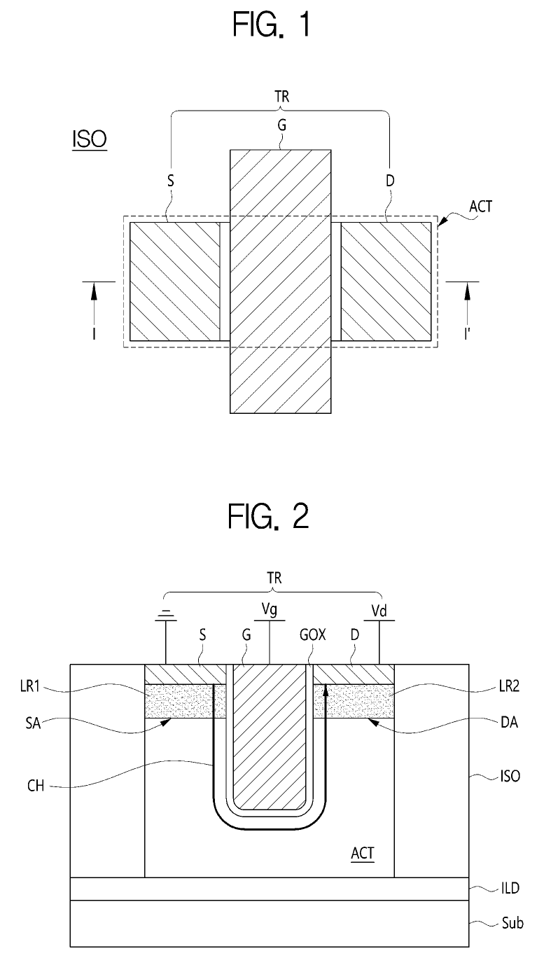

FIG. 1 is a plan view of a semiconductor device including an oxide semiconductor channel in accordance with embodiments, and FIG. 2 is a cross-sectional view taken along line I–I′ of FIG. 1.

Referring to FIGS. 1 and 2, a semiconductor device 10 may include a transistor TR.

The transistor TR may be integrated in an active region ACT. For example, the active region ACT may be defined at a substrate SUB. In one example, the active region ACT may be a portion of the substrate SUB.

In some embodiments, an interlayer dielectric ILD may be interposed between the active region ACT and the substrate SUB.

The active region ACT may include an oxide semiconductor material. For example, the oxide semiconductor material may include a compound of oxygen (O) and at least two metals among indium (In), zinc (Zn), gallium (Ga), and tin (Sn). For example, the oxide semiconductor material may include an IGZO material. The oxide semiconductor material may include CAAC (C-Axis Aligned Crystal)-IGZO.

Alternately, the oxide semiconductor material may include an amorphous IGZO, GZO, indium oxide (e.g., In₂O₃) doped with tungsten (W), or indium oxide (e.g., In₂O₃) doped with silicon (Si).

In embodiments, a conductivity of the CAAC-IGZO material may be determined by the indium concentration in the CAAC-IGZO material. The zinc concentration in the CAAC-IGZO material may enhance the CAAC characteristics, thereby providing structural stability of the CAAC-IGZO material. The gallium concentration in the CAAC-IGZO material may reduce oxygen vacancies in the IGZO material, thereby widening a bandgap of the CAAC-IGZO material.

The CAAC-IGZO material may have a higher energy for forming the oxygen vacancies compared to amorphous IGZO. Therefore, the probability of natural oxide formation in the CAAC-IGZO material may be lower than that in the amorphous IGZO material.

In addition, a carrier mobility of the CAAC-IGZO material may be higher than that of the amorphous silicon. Accordingly, an operating speed of a transistor using an oxide semiconductor material such as a CAAC-IGZO material as a channel may be faster than that of a transistor using a silicon material as a channel. In an embodiment, the indium concentration of the CAAC-IGZO material used as the active region ACT may range from about 1×10¹⁶ (e.g., 0.9 to 1.1×10¹⁶) to about 1×10¹⁸ cm⁻³ (0.9 to 1.1×10¹⁸ cm⁻³).

The active region ACT may be defined by an isolation layer ISO. The active region ACT may be surrounded by the isolation layer ISO. The isolation layer ISO may have a shallow trench isolation (STI) structure, although embodiments of the present disclosure are not limited thereto.

The transistor TR may include a gate G. The gate G may be disposed in the active region ACT. For example, the gate G may be formed in a buried type within the substrate SUB. Accordingly, the gate G may be referred to as a buried gate. A source region SA may correspond to an active region (e.g., a first portion of the active region) ACT at one side of the gate G, and a drain region DA may correspond to an active region (e.g., a second portion of the active region) ACT at the other side of the gate G. In some embodiments, at least one degenerated pattern (e.g., LR1, LR2, or both) may be interposed between the active region ACT and the source electrode S, or between the active region ACT and the drain electrode D, or both. For example, the first degenerated pattern LR1 may be interposed between the source region SA (or the first portion of the active region ACT) and the source electrode S, and the second degenerated pattern LR2 may be interposed between the drain region DA (or the second portion of the active region ACT) and the drain electrode D.

The transistor TR may further include a gate insulating layer GOX interposed between the gate G and the active region ACT. For example, the gate insulating layer GOX may include at least one of silicon oxide, silicon nitride, silicon oxynitride, and high-k materials. The high-k materials may be a material having a dielectric constant higher than those of silicon oxide and silicon nitride. For example, the high-k materials may include metal oxide, such as, hafnium oxide, aluminum oxide, or tantalum oxide.

The transistor TR may include a first degenerated pattern LR1 and a second degenerated pattern LR2. The first degenerated pattern LR1 may be formed on the source region SA. The second degenerated pattern LR2 may be formed on the drain region DA.

In an embodiment, the first and second degenerated patterns LR1 and LR2 may include an oxide containing one or more metal elements doped at a high concentration. For example, the metal element may include indium (In) or zinc (Zn). Accordingly, the first and second degenerated patterns LR1 and LR2 may include at least one of In₂O₃ and Zn₂O₃. In embodiments, the first and second degenerated patterns LR1 and LR2 may include a metal-rich oxide. Specifically, the degenerated patterns LR1 and LR2 may include at least one of indium-rich indium oxide, indium-rich indium tin oxide (ITO), and zinc-rich zinc oxide.

In an embodiment, the metal concentration of the first and second degenerated patterns LR1 and LR2 may range from about 1×10¹⁹ (e.g., 0.9 to 1.1×10¹⁹) to about 1×10²¹ cm⁻³ (e.g., 0.9 to 1.1×10²¹ cm⁻³).

Throughout the present disclosure, the term “metal-rich oxide” refers to an oxide in which one or more metal elements are included therein with an amount exceeding a stoichiometric ratio of the oxide or in an amount sufficient to form a degenerated semiconductor.

The transistor TR may include a source electrode S and a drain electrode D. In embodiments, the source electrode S may be arranged at one side of the gate G and the drain electrode D may be arranged at the other side of the gate G. The source electrode S may be formed on the first degenerated pattern LR1. For example, the source electrode S may be in contact with the first degenerated pattern LR1. The drain electrode D may be formed on the second degenerated pattern LR2. For example, the drain electrode D may be in contact with the second degenerated pattern LR2. The source electrode S and the drain electrode D may include a conductive material. To improve a contact resistance of the transistor TR, the source electrode S and the drain electrode D may include a metal material. Accordingly, Schottky junctions may be formed between the source electrode S and the first degenerated pattern LR1, and between the drain electrode D and the second degenerated pattern LR2 when the source electrode S and the drain electrode D may include the metal material.

In FIG. 2, CH may indicate a channel formed between the source electrode S and the drain electrode D when a gate voltage Vg is applied to the gate G. A drain voltage Vd is applied to the drain electrode D, and a ground voltage is applied to the source electrode S.

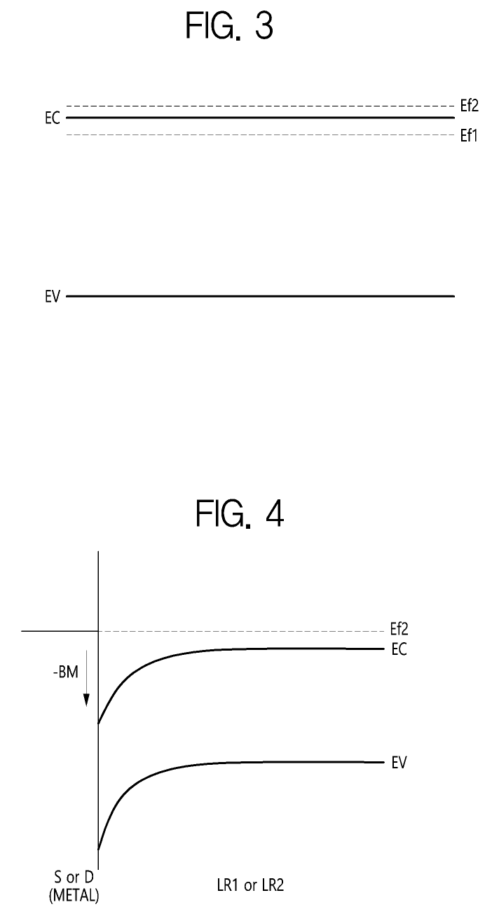

FIG. 3 is an energy band diagram of an oxide semiconductor material and a degenerated semiconductor material in accordance with embodiments. FIG. 4 is an energy band diagram of a junction between a source electrode (or a drain electrode) and a first degenerated pattern (or a second degenerated pattern) in accordance with embodiments.

Referring to FIG. 3, since the active region ACT including an oxide semiconductor material includes a relatively low metal concentration, a Fermi level Ef1 of the active region ACT may be positioned closer to a conduction band EC than to a valence band EV.

As shown in FIG. 4, a Fermi level Ef2 of the first or second degenerated pattern LR1 or LR2, which includes an excessive amount of metal atoms, may be positioned in the conduction band EC.

Without wishing to be limited by theory, when the first and second degenerated patterns LR1 and LR2 are coupled with the source electrode S and the drain electrode D, a negative Schottky barrier -BM may be formed at interfaces between the first and second degenerated patterns LR1 and LR2 and the source and drain electrodes S and D. When such negative Schottky barriers are formed in the source and drain electrodes S and D, a charge transport relatively easily occurs between the source electrode S and the first degenerated pattern LR1, and between the drain electrode D and the second degenerated pattern LR2. As a result, a contact resistance between the transistor TR and the source and drain electrodes S and D may be improved.

Further, the source electrode S and the drain electrode D may include at least one metal element having a relatively high Gibbs free energy (kJ/mol). For example, such a metal element having a relatively high Gibbs free energy (kJ/mol) may include at least one of TiN, Ti, Pt, Ni, Ru, and Mo. As is known, these metal elements exhibit a relatively low oxidation reactivity. Thus, forming a natural oxide layer at junction interfaces may be significantly reduced. For example, the junction interfaces may include one or more of an interface between the first degenerated patterns LR1 and the source electrode S, an interface between the second degenerated patterns LR2 and the drain electrode D, an upper surface of the source electrode S, and an upper surface of the drain electrode D. As the contact resistance decreases, electrical reliability of the transistor may be improved.

According to embodiments, the degenerated patterns may be formed on the source and drain regions of the oxide semiconductor device (e.g., transistor), to contact the source and drain electrodes, respectively. Because the degenerated patterns are formed on the active region as separate patterns, the contact resistance may be improved without significantly changing characteristics of the oxide semiconductor device (e.g., a threshold voltage).

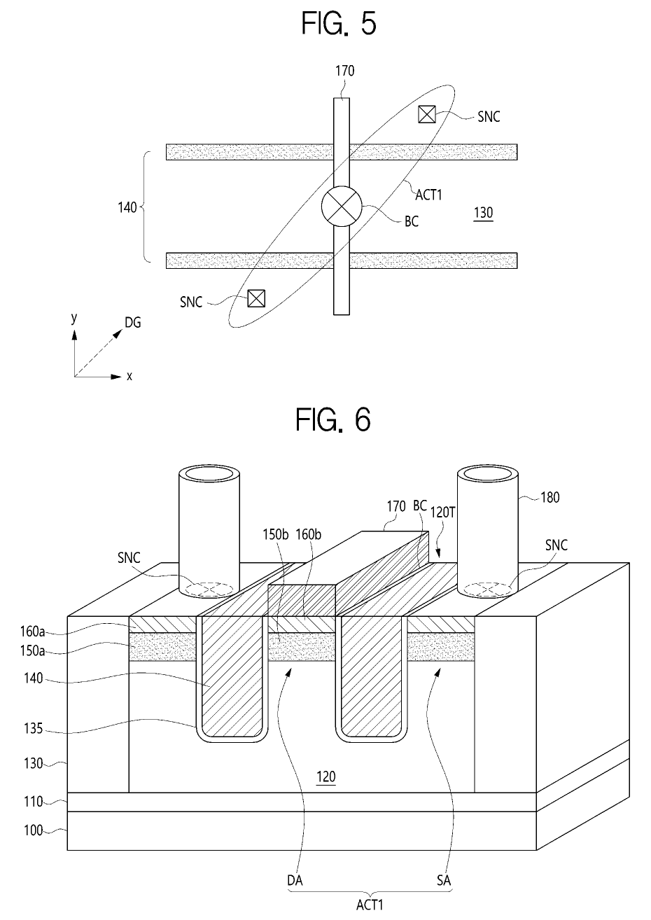

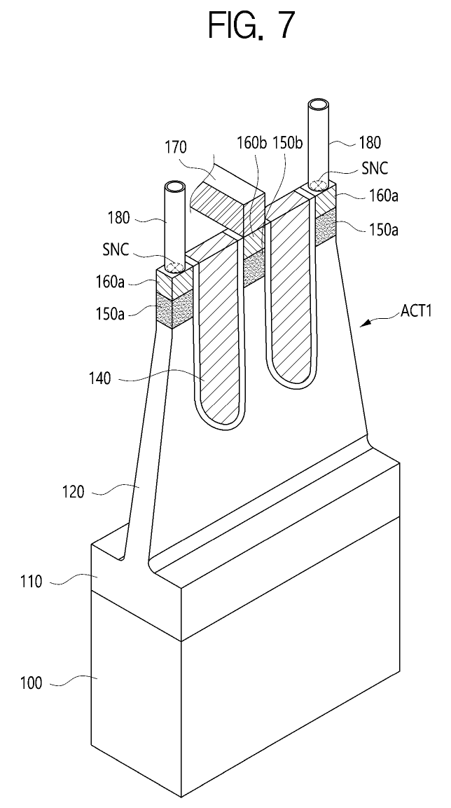

FIG. 5 is a schematic plan view of a DRAM memory cell in accordance with embodiments, and FIGS. 6 and 7 are schematic perspective views of a DRAM memory cell in accordance with embodiments.

Referring to FIGS. 5 and 6, an insulating interlayer 110 may be formed on a substrate 100. An oxide semiconductor layer 120 may be formed on the interlayer dielectric layer 110. The oxide semiconductor layer 120 may include an IGZO material containing indium (In), zinc (Zn), and gallium (Ga), and may include CAAC (C-Axis Aligned Crystal)-IGZO.

In another example, the oxide semiconductor layer 120 may alternatively be formed of amorphous IGZO, GZO, indium oxide (In₂O₃) doped with tungsten (W), or indium oxide (In₂O₃) doped with silicon (Si).

The oxide semiconductor layer 120 may have a relatively low probability of a natural oxide formation and a relatively high carrier mobility than a conventional silicon-based semiconductor material.

An isolation layer 130 may be formed in the oxide semiconductor layer 120 to define a plurality of active regions ACT1. Each active region ACT1 may have a bar-shaped planar structure, and a longitudinal direction of the bar-shaped active regions ACT1 may be arranged parallel to a diagonal direction DG of FIG. 5.

A plurality of trenches 120T may be formed in the active regions ACT1 and the isolation layer 130, with a regular interval. For example, the plurality of trenches 120T may extend along an x-axis direction of FIG. 5. For example, two trenches 120T may be formed for each active region ACT1 to define three fin regions within one active region ACT1. As shown in FIG. 7, the active region ACT1 may have a saddle fin structure.

A gate insulating layer 135 and a conductive layer may be sequentially formed on the active regions ACT1 and the isolation layer 130. The gate insulating layer 135 may be formed to have a substantially uniform thickness along the surface of the active regions ACT1. The gate insulating layer 135 may include a high-k dielectric material.

The conductive layer may be formed to a thickness sufficient to fill the trenches 120T. The conductive layer may be planarized and buried in the trenches 120T, thereby forming word lines 140 in the trenches 120T. For example, the word line 140 may be disposed on the active region ACT1 with the gate insulating layer 135 therebetween.

Because the word lines 140 are formed in a buried type inside the trenches 120T, the word lines 140 may be referred to as buried word lines. Although not shown in the drawings, a capping layer may further be formed on the word lines 140.

In an embodiment, a pair of word lines 140 may be disposed on one active region ACT1. A fin region between the pair of word lines 140 may serve as a common drain region DA, and two fin regions located outside the pair of word lines 140 may serve as source regions SA, respectively.

Degenerated patterns 150a and 150b may be formed on the source regions SA and the drain region DA. The degenerated patterns 150a and 150b may include oxide semiconductor materials in which metal such as indium (In) or zinc (Zn) are richly (or excessively) doped. For example, the degenerated patterns 150 may include In-rich indium oxide (e.g., In₂O₃₋ₓ) or Zn-rich zinc oxide (e.g., Zn₁₊ₓO). At least one of indium and zinc in the degenerated patterns 150 may have a concentration in the range of about 1×10¹⁹ to about 1×10²¹ cm⁻³.

In embodiments, the degenerated patterns 150a and 150b may be formed by an atomic layer deposition (ALD) or a chemical vapor deposition (CVD) using a precursor having a relatively high metal content. The precursor with such a relatively high metal content may include at least one of indium acetylacetonate, indium chloride (InCl₃), and trimethylindium (In(CH₃)₃). When the degenerated patterns 150a and 150b are formed by the ALD, the gas supply time of the indium-containing precursor may be set longer than the gas supply time of the oxygen-containing gas.

In embodiments, the degenerated patterns 150a and 150b may be formed by a sputtering manner using a target material with relatively high indium contents, such as, In₃O₄.

A source electrode 160a may be formed on the degenerated pattern 150a, and a drain electrode 160b may be formed on the degenerated pattern 150b. In some embodiments, the source electrode 160a may be disposed on a first portion of the active region ACT1 at one side of the word line 140, and a drain electrode 160b may be disposed on a second portion of the active region ACT1 at the other side of the word line 140. The source electrode 160a and the drain electrode 160b may include at least one metal material having a relatively high Gibbs free energy, such as TiN, Ti, Pt, Ni, Ru, W, Pd, or Mo.

A plurality of bit lines 170 may each be electrically connected to the drain electrode 160b. For example, the bit line 170 may be in contact with the drain electrode 160b. The plurality of bit lines 170 may extend in a y-axis direction of FIGS. 5 and 6. In FIG. 5, “BC” may be referred to a contact portion between the bit line 170 and the drain electrode 160b.

Storage electrodes 180 may be formed to be in contact with the degenerated patterns 150a formed on the source electrodes 160a. For example, the storage electrodes 180 may have a cylindrical shape. In FIG. 5, “SNC” may be referred to a contact portion between the degenerated pattern 150a and the storage electrode 180. In some embodiments, the storage electrode 180 may be in contact with the source electrode 160a. In FIG. 6, “SNC” may be referred to a contact portion between the source electrode 160a and the storage electrode 180.

As described in detail above, according to embodiments of the present disclosure, one or more degenerated patterns containing a relatively high concentration of the metal element(s) may be interposed between an active region and a source electrode, or between the active region and a drain electrode, or both. As a result, the contact resistance of a transistor including an oxide semiconductor material may be improved. Further, a carrier mobility characteristic and electrical characteristic of such an oxide semiconductor device may be improved.

In addition, according to embodiments of the present disclosure, since bit lines and storage electrodes may be formed of the materials having a relatively high Gibbs free energy, and an active region may include an oxide semiconductor material, formation of a natural oxide layer at contact interfaces may be reduced.

While some embodiments of the present disclosure have been described above, various embodiments of the present disclosure are not limited to these embodiments. Various modifications and variations may be made by those skilled in the art.

What is claimed is:

1. An oxide semiconductor device comprising:
an active region including an oxide semiconductor material;
a gate disposed in the active region;
a source electrode and a drain electrode, each of the source and drain electrodes including a metal material, the source electrode arranged at one side of the gate, and the drain electrode arranged at the other side of the gate; and
at least one degenerated pattern interposed between the active region and the source electrode, or between the active region and the drain electrode, or both, the degenerated pattern including a metal-rich oxide.

2. The oxide semiconductor device of claim 1, wherein the degenerated pattern includes at least one of In and Zn.

3. The oxide semiconductor device of claim 1, wherein a metal concentration of the degenerated pattern includes about 1×10¹⁹ to about 1×10²¹ cm⁻³.

4. The oxide semiconductor device of claim 1, wherein a Fermi level of the degenerated pattern is positioned in a conduction band of the degenerated pattern.

5. The oxide semiconductor device of claim 1, wherein the active region includes a compound of oxygen (O) and at least two metals among indium (In), zinc (Zn), gallium (Ga), and tin (Sn).

6. The oxide semiconductor device of claim 5, wherein a metal concentration of the active region includes about 1×10¹⁶ to about 1×10¹⁸ cm⁻³.

7. The oxide semiconductor device of claim 1, wherein the gate is buried in a trench.

8. The oxide semiconductor device of claim 7, further comprising a gate insulating layer interposed between the active region and the gate.

9. The oxide semiconductor device of claim 1, wherein the source electrode and the drain electrode comprise at least one of TiN, Ti, Pt, Ni, Ru, W, Pd, and Mo.

10. The oxide semiconductor device of claim 1, wherein the degenerated pattern includes at least one of indium-rich indium oxide, indium-rich indium tin oxide (ITO), and zinc-rich zinc oxide.

11. A semiconductor memory device comprising:
an active region including an oxide semiconductor layer disposed on a substrate;
a word line disposed on the active region;
a source electrode disposed on a first portion of the active region at one side of the word line;
a drain electrode disposed on a second portion of the active region at the other side of the word line;
a storage electrode in contact with the source electrode;
a bit line in contact with the drain electrode; and
at least one degenerated pattern interposed between the active region and the source electrode, or between the active region and the drain electrode, or both, the degenerated pattern including a metal-rich oxide.

12. The semiconductor memory device of claim 11, wherein the degenerated pattern includes at least one of In and Zn.

13. The semiconductor memory device of claim 11, wherein a metal concentration of the degenerated pattern includes about 1×10¹⁹ to about 1×10²¹ cm⁻³.

14. The semiconductor memory device of claim 11, wherein a Fermi level of the degenerated pattern is positioned in a conduction band of the degenerated pattern.

15. The semiconductor memory device of claim 11, wherein the active region includes a compound of oxygen (O) and at least two metals among indium (In), zinc (Zn), gallium (Ga), and tin (Sn).

16. The semiconductor memory device of claim 15, wherein a metal concentration of the active region includes about 1×10¹⁶ to about 1×10¹⁸ cm⁻³.

17. The semiconductor memory device of claim 11, wherein the word line is buried in a trench.

18. The semiconductor memory device of claim 17, further comprising a gate insulating layer interposed between the active region and the word line.

19. The semiconductor memory device of claim 11, wherein the source electrode and the drain electrode include at least one of TiN, Ti, Pt, Ni, Ru, W, Pd, and Mo.

20. The oxide semiconductor device of claim 11, wherein the degenerated pattern includes at least one of indium-rich indium oxide, indium-rich indium tin oxide (ITO), and zinc-rich zinc oxide.
